(19) United States
(12) Patent Application Publication
(10) Pub. No.: US 2015/0084678 A1
(43) Pub. Date: Mar. 26, 2015

(54) PHASE LOCKED LOOP CIRCUIT

(71) Applicant: NIHON DEMPA KOGYO CO., LTD., TOKYO (JP)

(72) Inventor: MINORU FUKUDA, SAITAMA (JP)

(21) Appl. No.: 14/469,598

(22) Filed: Aug. 27, 2014

(30) Foreign Application Priority Data
Sep. 26, 2013 (JP) 2013-200341

(51) Int. Cl. H03L 7/093; H03L 5/00; H03L 7/099

(52) U.S. Cl. CPC H03L 7/093; H03L 7/099; H03L 5/00
USPC 327/156

(57) ABSTRACT

A Phase Locked Loop (PLL) circuit is provided. The PLL includes a voltage controlled oscillator (VCO) for outputting an oscillation signal of a frequency corresponding to an inputted voltage, a frequency divider for dividing the oscillation signal and output a frequency-divided signal, a phase comparator for comparing a phase of the frequency-divided signal and the phase of an input signal from the outside and output a first phase comparison signal and a second phase comparison signal which have different polarities, a differential amplifier circuit for outputting a control voltage based on a voltage difference between the first phase comparison signal and the second phase comparison signal to the VCO, a level shift circuit for outputting a level-shifted signal which is made by shifting a direct current level of the second phase comparison signal, and an amplifier circuit for outputting an amplified signal which is an amplified level-shifted signal.

### CROSS-REFERENCE TO RELATED APPLICATIONS

This application claims the priority benefit of Japan application serial no. 2013-200341, filed on Sep. 26, 2013. The entirety of the above-mentioned patent application is hereby incorporated by reference herein and made a part of this specification.

### TECHNICAL FIELD

The present disclosure relates to a Phase Locked Loop (PLL) circuit.

### BACKGROUND OF THE INVENTION

In a PLL circuit, a phase difference signal outputted from a phase comparator is smoothed by a low-pass filter according to a phase difference between an oscillation signal outputted from a voltage controlled oscillator (VCO) and a reference signal inputted from the outside, and the smoothed signal is inputted to the VCO as a control signal which controls the VCO. The VCO outputs an oscillation signal of a frequency corresponding to a voltage of the inputted control signal.

When the frequencies of the reference signal inputted to the phase comparator and the oscillation signal outputted from the VCO fluctuate, a duty of the output of the phase comparator is changed to maintain the frequencies of the reference signal and the oscillation signal in a locked state. As a result, the relationship between the phase position of the reference signal and the phase position of the oscillation signal inputted to the phase comparator is changed, and Japanese Examined Patent Application Publication No. S63-19094 discloses an example in which the phase positions of the reference signal and the oscillation signal are detected, integrated, and added to a control voltage of the VCO for suppressing the fluctuation of phase positions of the two signals.

However, because a conventional PLL circuit detects the phase positions of the reference signal and the oscillation signal, and performs integration, there was a problem of an increase of jitter in the oscillation signal and an increase of phase noise.

The present disclosure is created in view of the aforementioned circumstances, and the present disclosure is to provide the PLL circuit which can prevent the increase of the jitter and can reduce the phase noise.

### SUMMARY

The Phase Locked Loop (PLL) circuit according to the present disclosure comprises a voltage controlled oscillator (VCO) configured to output an oscillation signal having a frequency corresponding to an inputted voltage, a frequency divider configured to divide the oscillation signal and output a frequency-divided signal, a phase comparator configured to compare a phase of the frequency-divided signal and a phase of an input signal from the outside and output a first phase comparison signal and a second phase comparison signal which have different polarities, a differential amplifier circuit configured to output a control voltage based on a voltage difference between the first phase comparison signal and the second phase comparison signal to the VCO, a level shift circuit configured to output a level-shifted signal which is made by shifting a direct current (DC) level of the second phase comparison signal, and an amplifier circuit configured to output an amplified signal which is an amplified level-shifted signal, wherein the differential amplifier circuit generates the control voltage based on the voltage difference between the amplified signal and the first phase comparison signal.

### BRIEF DESCRIPTION OF THE DRAWINGS

FIG. 1 shows a configuration of a PLL circuit according a first exemplary embodiment.

FIG. 2 shows a configuration of a PLL circuit according a second exemplary embodiment.

### DESCRIPTION OF EXEMPLARY EMBODIMENTS

### First Exemplary Embodiment

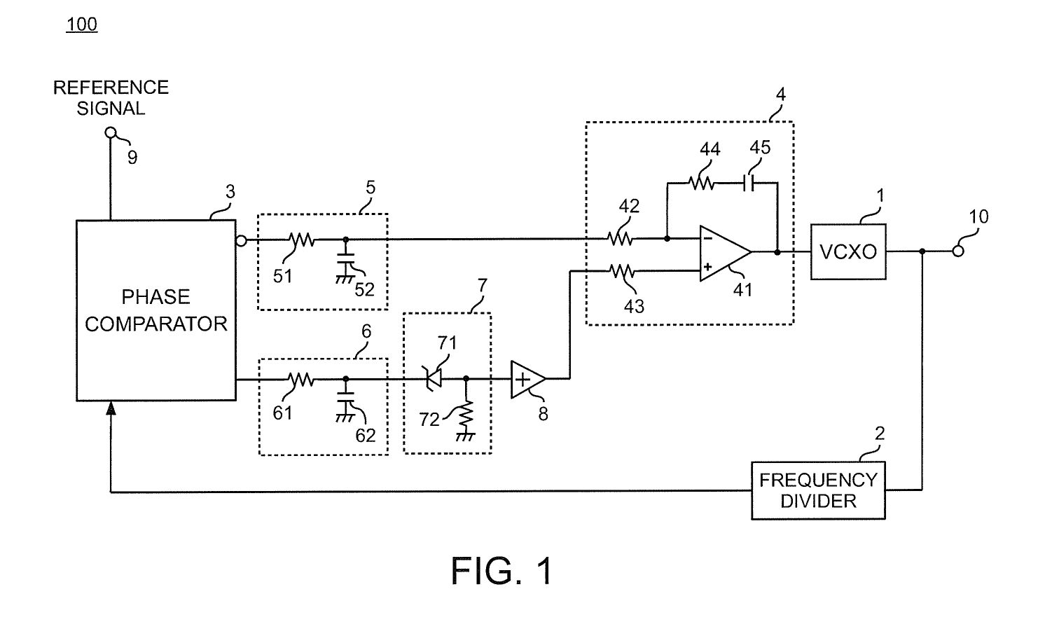

FIG. 1 shows a configuration of a PLL circuit 100 according to a first exemplary embodiment. The PLL circuit 100 includes a voltage controlled oscillator (VCO) 1, a frequency divider 2, a phase comparator 3, a differential amplifier circuit 4, a first low-pass filter 5, a second low-pass filter 6, a level shift circuit 7, an amplifier circuit 8, an input terminal 9, and an output terminal 10. In the PLL circuit 100, the reference signal is inputted from the input terminal 9 and the oscillation signal synchronized with the reference signal is outputted from the output terminal 10.

The VCO 1 outputs the oscillation signal of a frequency corresponding to an inputted voltage. The VCO 1 is, for example, a voltage controlled crystal oscillator (VCXO), and outputs the oscillation signal of the frequency corresponding to the voltage of a control signal inputted from the differential amplifier circuit 4 to the output terminal 10 and the frequency divider 2.

The frequency divider 2 outputs a frequency-divided signal by dividing the oscillation signal inputted from the VCO 1. A division ratio which is a ratio between the frequency of the oscillation signal and the frequency of the frequency-divided signal is decided, for example, based on the frequency of the reference signal inputted from the input terminal 9 to the PLL circuit 100. The frequency of the frequency-divided signal is equal to, for example, the frequency of the reference signal.

The phase comparator 3 compares a phase of the frequency-divided signal and a phase of the input signal from the outside, and outputs a first phase comparison signal and a second phase comparison signal, which have different polarities. The phase comparator 3 is, for example, an R-S type phase comparator which changes levels of the first phase comparison signal and the second phase comparison signal at change timings of the level of the frequency-divided signal and change timings of the level of the input signal. The first phase comparison signal and the second phase comparison signal are signals which are logically inverted relative to each other, the first phase comparison signal is outputted from an inverting output terminal of the phase comparator 3, and the second phase comparison signal is outputted from a non-inverting output terminal of the phase comparator 3.

The first phase comparison signal outputted from the phase comparator 3 is inputted to a negative side input terminal of the differential amplifier circuit 4 through the first low-pass filter 5. The second phase comparison signal outputted from the phase comparator 3 is inputted to a positive side input terminal of the differential amplifier circuit 4 through the second low-pass filter 6, the level shift circuit 7, and the amplifier circuit 8.

The differential amplifier circuit 4 outputs a control voltage based on a voltage difference between the first phase comparison signal and the second phase comparison signal to the VCO 1. The differential amplifier circuit 4 includes an operational amplifier 41, a resistance 42, a resistance 43, a resistance 44, and a capacitor 45. The resistance 42 is connected to the negative side input terminal of the operational amplifier 41 and the first phase comparison signal is inputted to the resistance 42 through the first low-pass filter 5. The resistance 43 is connected to the positive side input terminal of the operational amplifier 41 and the second phase comparison signal is inputted to the resistance 43 through the second low-pass filter 6, the level shift circuit 7, and the amplifier 8.

The resistance 44 and the capacitor 45 are provided to a negative feedback path between the negative side input terminal and the output terminal of the operational amplifier 41. Because the capacitor 45 is provided to the negative feedback path, the control voltage which is proportional to an integrated value of a potential difference between the negative side input terminal and the positive side input terminal of the operational amplifier 41 is outputted from the output terminal of the operational amplifier 41.

The first low-pass filter 5, which passes frequency components of the first phase comparison signal below the first frequency, is provided between the inverting output terminal of the phase comparator 3 and the differential amplifier circuit 4. The first low-pass filter 5 includes, for example, a resistance 51 connected to the inverting output terminal of the phase comparator 3 and a capacitor 52 provided between (i) a connection point between the resistance 51 and the resistance 42 and (ii) a ground. The first low-pass filter 5 may be a lag lead filter whose resistance is provided in series with the capacitor 52 between (i) the connection point between the resistance 51 and the resistance 42 and (ii) the ground.

The second low-pass filter 6, which passes frequency components of the second phase comparison signal below the second frequency that is lower than the first frequency, is provided between the non-inverting output terminal of the phase comparator 3 and the level shift circuit 7. The second low-pass filter 6 includes, for example, a resistance 61 connected to the non-inverting output terminal of the phase comparator 3 and a capacitor 62 provided between (i) the connection point between the resistance 61 and a zener diode 71 and (ii) the ground. The second low-pass filter 6 may be the lag lead filter whose resistance is provided in series with the capacitor 62 between (i) the connection point between the resistance 61 and the zener diode 71 and (ii) the ground.

The level shift circuit 7 outputs a level-shifted signal that is made by shifting the level of a direct current (DC) level of the second phase comparison signal. The level shift circuit 7 includes the zener diode 71 and a resistance 72. The cathode of the zener diode 71 is electrically connected to the non-inverting output terminal of the phase comparator 3 through the second low-pass filter 6. The anode of the zener diode 71 is connected to the amplifier circuit 8. The resistance 72 is provided between (i) the connection point between the anode of the zener diode 71 and the amplifier circuit 8 and (ii) the ground, and generates the voltage of the level-shifted signal level-shifted by the zener diode 71.

The level shift circuit 7 lowers the voltage of the smoothed signal which is outputted from the second low-pass filter 6 and outputs the signal to the amplifier circuit 8. For example, a case where a zener voltage of the level shift circuit 7 is 1.5V is considered. When the voltage of the smoothed signal outputted from the second low-pass filter 6 is 3.0V, the level shift circuit 7 outputs the level-shifted signal of 1.5V. When the voltage of the smoothed signal outputted from the second low-pass filter 6 is 2.5V, the level shift circuit 7 outputs the level-shifted signal of 1.0V. When the voltage of the smoothed signal outputted from the second low-pass filter 6 is 2.0V, the level shift circuit 7 outputs the level-shifted signal of 0.5V.

The amplifier circuit 8 outputs an amplified signal, which is an amplified level-shifted signal, to the positive side input terminal of the operational amplifier 41 through the resistance 43. The amplifier circuit 8 is, for example, a non-inverting amplifier having an operational amplifier or a transistor, which outputs the voltage of a positive value generated by amplifying the positive voltage with a prescribed amplification factor.

The prescribed amplification factor of the amplifier circuit 8 is determined based on a supply voltage driving the VCO 1 and a voltage range that the level shift circuit 7 level-shifts. Specifically, the prescribed amplification factor is set so that the voltage outputted from the amplifier circuit 8 is an intermediate voltage when the smoothed signal, which is equal to the intermediate voltage between the supply voltage driving the VCO 1 and a ground potential, is inputted to the level shift circuit 7.

If the supply voltage is 5.0V, for instance, the level-shifted signal of 1.0V is inputted to the amplifier circuit 8 when the smoothed signal of 2.5V is inputted to the level shift circuit 7. The amplification factor of the amplifier circuit 8 is set to be 2.5 so as to output the amplified signal of 2.5V by amplifying the level-shifted signal of 1.0V.

If the amplification factor of the amplifier circuit 8 is set to be 2.5, when the voltage of the smoothed signal is 3.0V, the voltage of the amplified signal outputted from the amplifier circuit 8 is calculated to be (3.0V-1.5V)×2.5=3.75V. Therefore, in comparison with the case when the smoothed signal outputted from the second low-pass filter 6 is directly inputted to the positive side input terminal of the operational amplifier 41, a larger voltage is inputted to the positive side input terminal of the operational amplifier 41 and integrated. That is, the variation of the duty of the output of the phase comparator 3 is amplified, integrated, and added to the control voltage to be inputted to the VCO 1. As a result, the fluctuation of the phase positions of the reference signal and the oscillation signal can be suppressed when the duty of the second phase comparison signal changes and the level of the smoothed signal increases because of the fluctuation of the reference signal or the oscillation signal.

When the voltage of the smoothed signal is 2.0V, the voltage of the amplified signal outputted from the amplifier circuit 8 is calculated to be (2.0V-1.5V)×2.5=1.25V. Therefore, in comparison with the case when the smoothed signal outputted from the second low-pass filter 6 is directly inputted to the positive side input terminal of the operational amplifier 41, a lower voltage is inputted to the positive side input terminal of the operational amplifier 41, integrated, and added to the control voltage to be inputted to the VCO 1. Thus, the fluctuation of the phase positions of the reference signal and the oscillation signal can be suppressed even when the duty of the second phase comparison signal changes and the level of the smoothed signal decreases because of the fluctuation of the reference signal or the oscillation signal.

The second frequency which is an upper limit of a frequency bandwidth that the second low-pass filter 6 can pass is, for example, 1/10 of the first frequency which is the upper limit of the frequency bandwidth that the first low-pass filter 5 can pass. The fluctuation of the smoothed signal outputted from the second low-pass filter 6 at a frequency higher than the second frequency is suppressed because the second frequency is lower than the first frequency. Thus, even when the smoothed signal is amplified by the amplifier circuit 8, a control system of the VCO 1 does not become unstable because the VCO 1 does not react against the temporary fluctuation of the frequency higher than the second frequency. As a result, the VCO 1 can suppress the fluctuation of the phase positions of the reference signal and the oscillation signal while suppressing the effect of the temporary fluctuation of reference signal or the oscillation signal.

As described above, the PLL circuit 100 according to the first exemplary embodiment includes the level shift circuit 7 which outputs the level-shifted signal in which the DC level of the second phase comparison signal is shifted and the amplifier circuit 8 which outputs the amplified signal that is the amplified level-shifted signal, provided between the shift comparator 3 and the positive side input terminal of the differential amplifier circuit 4. With such a configuration, the fluctuation of the phase positions of the two signals can be suppressed, not by detecting the phase positions of the reference signal and the oscillation signal, but by amplifying, integrating, and adding the variation of the duty of the output of the phase comparator 3 to the control voltage of the VCO 1. According to the present exemplary embodiment, jitter does not increase and the phase noise can be reduced because the fluctuation of the integration output is moderated.

### Second Exemplary Embodiment

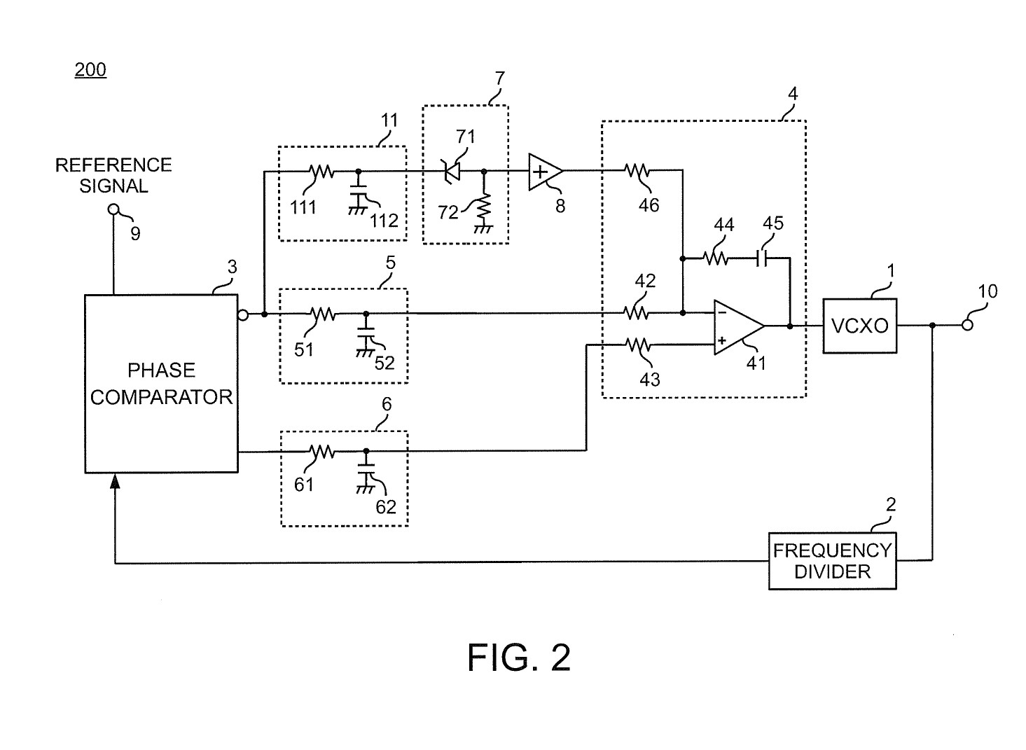

FIG. 2 shows a configuration of a PLL circuit 200 according the second exemplary embodiment. The PLL circuit 200 is different from the PLL circuit 100 according to the first exemplary embodiment in a point that the level shift circuit 7 and the amplifier circuit 8 are provided between the inverting output terminal of the phase comparator 3 and the negative side input terminal of the operational amplifier 41 in the PLL circuit 200.

Specifically, the level shift circuit 7 and the amplifier circuit 8 are not provided between the non-inverting output terminal of the phase comparator 3 and the positive side input terminal of the operational amplifier 41, but a third low-pass filter 11, the level shift circuit 7, the amplifier circuit 8, and the resistance 46 are provided in parallel with the first low-pass filter 5 and the resistance 42 between the inverting output terminal of the phase comparator 3 and the negative side input terminal of the operational amplifier 41.

The third low-pass filter 11 has the same configuration as the first low-pass filter 5, and includes a resistance 111 connected to the inverting output terminal of the phase comparator 3 and a capacitor 112 provided between (i) the connection point between the resistance 111 and the zener diode 71 and (ii) the ground. A signal smoothed in the third low-pass filter 11 is inputted to the level shift circuit 7 and is level-shifted in the level shift circuit 7, and the level-shifted signal is amplified in the amplifier circuit 8.

The voltage of the amplified signal outputted from the amplifier circuit 8 is added to the voltage to be inputted to the negative side input terminal of the operational amplifier 41 through the first low-pass filter 5 and the resistance 42. The voltage of the control signal outputted from the operational amplifier 41 becomes larger when the voltage of the amplified signal outputted from the amplifier circuit 8 is added than when the voltage of the amplified signal is not added. As a result, the fluctuation of the phase positions of the reference signal and the oscillation signal can be suppressed when the duty of the second phase comparison signal changes and the level of the smoothed signal increases because of the fluctuation of the reference signal and the oscillation signal.

As described above, the PLL circuit 200 according to the second exemplary embodiment includes the level shift circuit 7 which outputs the level-shifted signal made by shifting a DC level of the first phase comparison signal and the amplifier circuit 8 which outputs the amplified signal that is made by amplifying the level-shifted signal, provided between the shift comparator 3 and the negative side input terminal of the differential amplifier circuit 4. With such a configuration, the fluctuation of the phase positions of the reference signal and the oscillation signal can be suppressed, and therefore the increase of the jitter is prevented and the phase noise can be reduced.

The present disclosure is described with the embodiments but the technical scope of the present disclosure is not limited to the scope described in the above embodiment. It is apparent for those skilled in the art that it is possible to make various changes and modifications to the embodiment. It is apparent from the description of the scope of the claims that the forms added with such changes and modifications are included in the technical scope of the present disclosure.

For example, although the case where the zener diode 71 is a zener diode is described in the above exemplary embodiments, other elements may be utilized as the element which level-shifts the smoothed signal. For example, a plurality of diodes connected in series may be utilized or a resistance may be utilized to lower the voltage.

What is claimed is:

1. A Phase Locked Loop (PLL) circuit, comprising:
a voltage controlled oscillator (VCO) configured to output an oscillation signal having a frequency corresponding to an inputted voltage;
a frequency divider configured to divide the oscillation signal and to output a frequency-divided signal;
a phase comparator configured to compare a phase of the frequency-divided signal and a phase of an input signal from the outside, and to output a first phase comparison signal and a second phase comparison signal which have different polarities;
a differential amplifier circuit configured to output a control voltage based on a voltage difference between the first phase comparison signal and the second phase comparison signal to the VCO;
a level shift circuit configured to output a level-shifted signal which is made by shifting a direct current (DC) level of the second phase comparison signal; and
an amplifier circuit configured to output an amplified signal which is an amplified level-shifted signal, wherein
the differential amplifier circuit generates the control voltage based on the voltage difference between the amplified signal and the first phase comparison signal.

2. The PLL circuit according to claim 1, further comprising:
a first low-pass filter provided between the phase comparator and the differential amplifier circuit, and configured to pass frequency components whose frequencies are lower than or equal to a first frequency in the first phase comparison signal; and
a second low-pass filter provided between the phase comparator and the level shift circuit, and configured to pass frequency components whose frequencies are lower or equal to a second frequency that is lower than the first frequency in the second phase comparison signal.

3. The PLL circuit according to claim 1, wherein
the level shift circuit is provided between the phase comparator and a positive side input terminal of the differential amplifier circuit.

4. The PLL circuit according to claim 1, wherein
the level shift circuit is provided between the phase comparator and a negative side input terminal of the differential amplifier circuit.

5. The PLL circuit according to claim 1, wherein
the level shift circuit includes:
a zener diode whose cathode is connected to the phase comparator, and
a resistance provided between the anode of the zener diode and a ground.
